(19) United States
(12) Patent Application Publication
(10) Pub. No.: US 2017/0207787 A1
(43) Pub. Date: Jul. 20, 2017

(54) DESIGNING PROGRAM OF PROGRAMMABLE LOGIC DEVICE, PROGRAMMABLE LOGIC DEVICE DESIGNING APPARATUS, AND METHOD THEREOF

(71) Applicant: FUJITSU LIMITED, Kawasaki-shi (JP)

(72) Inventors: Shinichiro Uekusa, Kawasaki (JP); YOSHINORI MESAKI, YOKOHAMA (JP)

(73) Assignee: FUJITSU LIMITED, Kawasaki-shi (JP)

(21) Appl. No.: 15/352,676

(22) Filed: Nov. 16, 2016

(30) Foreign Application Priority Data
Jan. 14, 2016 (JP) 2016-005071

(51) Int. Cl. H03K 19/177; H03K 19/173

(52) U.S. Cl. CPC H03K 19/17764; H03K 19/17728; H03K 19/1735

(57) ABSTRACT

In the designing program of a programmable logic device, the logical expression of the combinational circuit is acquired from the arranged wire information on the programmable logic device. Next, a wire delay amount connected to an input port of the combinational circuit is acquired from the arranged wire information. Next, the input ports of the connection destinations of the wires connected to at least two input ports of the combinational circuit are exchanged so that the input order coincides with the input order corresponding to the logical expression of the combinational circuit stored in the input port change table. This processing is based on a cell delay amount of the combinational circuit and the wire delay amount. Then, the logical expression of the combinational circuit is changed in accordance with the exchange of the input ports of the connection destinations of the wires.

### CROSS-REFERENCE TO RELATED APPLICATION

This application is based upon and claims the benefit of priority of the prior Japanese Patent Application No. 2016-5071, filed on Jan. 14, 2016, the entire contents of which are incorporated herein by reference.

### FIELD

The present invention relates to a designing program of a programmable logic device, a programmable logic device designing apparatus, and a method thereof.

### BACKGROUND

In a semiconductor device, a technique for preventing a pulse having a short width, also referred to as a hazard, spike, or glitch, is known. For example, a decode circuit including input logic gates having three or more input ports which are input signals including a clock signal is known (e.g., see Patent Document 1). Further, it is known to reduce wasteful toggles of an internal node in a circuit, by using a cell which removes pulses whose width are less than or equal to a predetermined pulse width from input signal pulses (e.g., see Patent Document 2). Furthermore, a logic circuit is known in which input data and a clock signal are input to a flip-flop and a timing generation circuit (e.g., see Patent Document 3). The logic circuit has a glitch removal circuit and a latch circuit between combinational circuits in the logic circuit, the glitch removal circuit is configured to remove glitches, an output of a timing generation circuit inputs to the latch circuit, and the latch circuit removes a glitches that are not removed by the glitch removal circuit. Further, it is known to reduce spikes by replacing a spike pulse occurrence source block in which a glitch occurs with an appropriate equivalent block which inserts into a delay cell (e.g., see Patent Document 4).

### PATENT DOCUMENT

[Patent Document 1] Japanese Laid Open Patent Document No. 2002-43901

[Patent Document 2] Japanese Laid Open Patent Document No. H10-233663

[Patent Document 3] Japanese Laid Open Patent Document No. 2015-95786

[Patent Document 4] Japanese Laid Open Patent Document No. 2002-157293

### SUMMARY

In one aspect, a designing program of a programmable logic device uses an input port change table showing a relationship between a logical expression of a combinational circuit and an input order of input signals that are input to a combinational circuit, which minimizes the number of glitches that occur in the combinational circuit. In the designing program of a programmable logic device, the logical expression of the combinational circuit is acquired from the arranged wire information on the programmable logic device. Next, a wire delay amount connected to an input port of the combinational circuit is acquired from the arranged wire information. Next, the input ports of the connection destinations of the wires connected to at least two input ports of the combinational circuit are exchanged so that the input order coincides with the input order corresponding to the logical expression of the combinational circuit stored in the input port change table. This processing is based on a cell delay amount of the combinational circuit and the wire delay amount. Then, the logical expression of the combinational circuit is changed in accordance with the exchange of the input ports of the connection destinations of the wires.

The object and advantages of the embodiments will be realized and attained by means of the elements and combination particularly pointed out in the claims.

It is to be understood that both the foregoing general description and the following detailed description are exemplary and explanatory and are not restrictive of the invention.

### BRIEF DESCRIPTION OF DRAWING

FIG. 1 is a partial circuit block diagram of an FPGA;

FIG. 2A is a diagram illustrating the first LUT illustrated in FIG. 1;

FIG. 2B is a diagram illustrating an example of a timing chart of input/output signals of the first LUT illustrated in FIG. 2A;

FIG. 3 is a diagram illustrating an example of simulation results in which glitches occur;

FIG. 4 is a block diagram of a programmable logic device designing apparatus according to a first embodiment;

FIG. 5 is a flowchart of configuration data generation processing by the PLD designing apparatus illustrated in FIG. 4;

FIG. 6 is a flowchart illustrating a more detailed processing flow of the processing at S103 illustrated in FIG. 5;

FIG. 7A is a diagram illustrating an example of the first LUT;

FIG. 7B is a diagram illustrating another example of the first LUT;

FIG. 8 is a diagram illustrating an input port change table;

FIG. 9 is a table (Part 1) that is used in the processing to determine the input order of the input signals which minimizes the number of glitches that occur in the logical expression (X=A or (B and C));

FIG. 10 is a table (Part 2) that is used in the processing to determine the input order of the input signals which minimizes the number of glitches that occur in the logical expression (X=A or (B and C));

FIG. 11 is a block diagram of a PLD designing apparatus according to a second embodiment;

FIG. 12 is a flowchart of configuration data generation processing by the PLD designing apparatus illustrated in FIG. 11;

FIG. 13 is a flowchart illustrating a more detailed processing flow of the processing at S304 illustrated in FIG. 12;

FIG. 14A is a diagram illustrating an LUT in which input signals are input to a first input port a to a third input port c and a fourth input port d is an unused input port;

FIG. 14B is a diagram illustrating a state where the processing at S405 is performed in the LUT illustrated in FIG. 14A;

FIG. 15 is a block diagram of a PLD designing apparatus according to a third embodiment;

FIG. 16 is a flowchart of configuration data generation processing by the PLD designing apparatus illustrated in FIG. 15;

FIG. 17 is a flowchart illustrating a more detailed processing flow of the processing at S505 illustrated in FIG. 16;

FIG. 18A is a diagram illustrating an example of an LUT;

FIG. 18B is a diagram illustrating another example of an LUT;

FIG. 19 is diagram showing an example of a timing chart of input/output signals of the LUT illustrated in FIG. 18B;

FIG. 20 is a diagram illustrating the state of configuration data for which the configuration data generation processing by the PLD designing apparatus illustrated in FIG. 4 is not performed; and

FIG. 21 is a diagram illustrating the state of configuration data for which the configuration data generation processing by the PLD designing apparatus illustrated in FIG. 4 has been performed.

### DESCRIPTION OF EMBODIMENTS

In the following, with reference to the drawings, a designing program of a programmable logic device, a programmable logic device designing apparatus, and a method thereof according to the present invention are explained. However, the technical scope of the present invention is not limited to those embodiments.

### Outline of Designing Program of Programmable Logic Device According to Embodiment

A programmable logic device is known, which is also referred to as an FPGA (Field Programmable Gate Array), and is a logic circuit that is reconfigured in accordance with a change in a mounted circuit configuration. The FPGA has a number of basic logic cell circuits and connection switch circuits configured to connect between the basic logic cell circuits, and each basic logic cell circuit is configured to perform a desired operation and is connected via the connection switch circuit. In the FPGA, a combinational circuit is implemented by a lookup table (LUT).

However, the delay amount from the input port to the output port of the LUT in the FPGA is a value fixed for each input port, and therefore it is not easy to insert a delay element in order to reduce glitches. Further, since it is not easy to change a connection relationship between specific wires, arranged wire processing and logic verification processing using a test pattern are performed in order to specify the source of the occurrence of a glitch, and therefore the period for designing may be increased.

An object of one embodiment is to provide a designing program of a programmable logic device configured to reduce the number of glitches without increasing the period for designing.

The designing program according to the embodiment uses an input port change table showing a relationship between a logical expression of a combinational circuit and an input order of input signals that are input to the combinational circuit, which minimizes the number of glitches in the combinational circuit. In the designing program according to the embodiment, the input ports of the connection destinations of the wires connected to at least two input ports of the combinational circuit and the logical expressions are exchanged so that the input order coincides with the input order corresponding to the logical expression of the combinational circuit stored in the input port change table. In the designing program according to the present embodiment, the number of glitches in the combinational circuits is minimized theoretically by exchanging the input ports of the connection destinations of the wires and the logical expressions so that the input order coincides with the input order corresponding to the logical expression of the combinational circuit stored in the input port change table.

In one embodiment, a designing program of a programmable logic device configured to reducing the number of glitches in the combinational circuits without increasing the period for designing is provided.

(Mechanism of Occurrence of Glitch in FPGA)

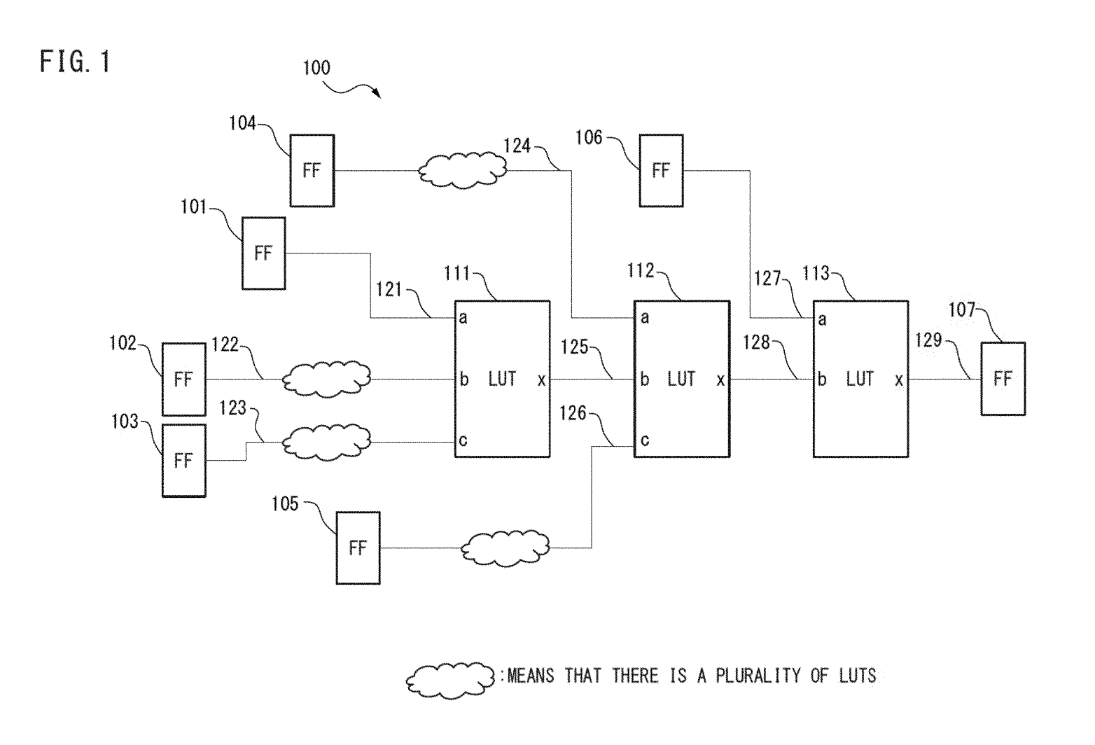

FIG. 1 is a partial circuit block diagram of an FPGA.

An FPGA 100 has a first flip-flop 101 to a seventh flip-flop 107 and a first LUT 111 to a third LUT 113. An input signal is input from the first flip-flop 101 to a first input port a of the first LUT 111 via a first wire 121. An input signal is input from the second flip-flop 102 to a second input port b of the first LUT 111 via a second wire 122 and a plurality of LUTs, not illustrated. An input signal is input from the third flip-flop 103 to a third input port c of the first LUT 111 via a third wire 123 and a plurality of LUTs, not illustrated. An input signal is input from the fourth flip-flop 104 to a first input port a of the second LUT 112 via a fourth wire 124 and a plurality of LUTs, not illustrated. An input signal is input from an output port x of the first LUT 111 to a second input port b of the second LUT 112 via a fifth wire 125. An input signal is input from the fifth flip-flop 105 to a third input port c of the second LUT 112 via a sixth wire 126 and a plurality of LUTs, not illustrated. An input signal is input from the sixth flip-flop 106 to a first input port a of the third LUT 113 via a seventh wire 127 and to a second input port b of the third LUT 113, an input signal is input from an output port x of the second LUT 102 via an eighth wire 128. An output port x of the third LUT 113 outputs an output signal to the seventh flip-flop 107 via a ninth wire 129.

The FPGA 100 is designed so that the delay amount after an input data signal is input to the flip-flop in the previous stage until the input data signal is input to the flip-flop in the next stage is smaller than a predetermined upper limit delay amount specified by a clock frequency. In other words, the FPGA 100 is designed so that the delay amount after an input data signal is input to the first flip-flop 101 to the sixth flip-flop 106 until the input data signal is input to the seventh flip-flop 107 is smaller than the predetermined upper limit delay amount. For example, when the frequency of the clock signal is 200 MHz, the upper limit delay amount is 5 ns. Thus, the FPGA 100 is designed so that the delay amount after an input data signal is input to the first flip-flop 101 to the sixth flip-flop 106 until the input data signal is input to the seventh flip-flop 107 is less than 5 ns.

However, the difference between the delay amounts between the input signals that are input to the first LUT 111 to the third LUT 113 is not taken into consideration.

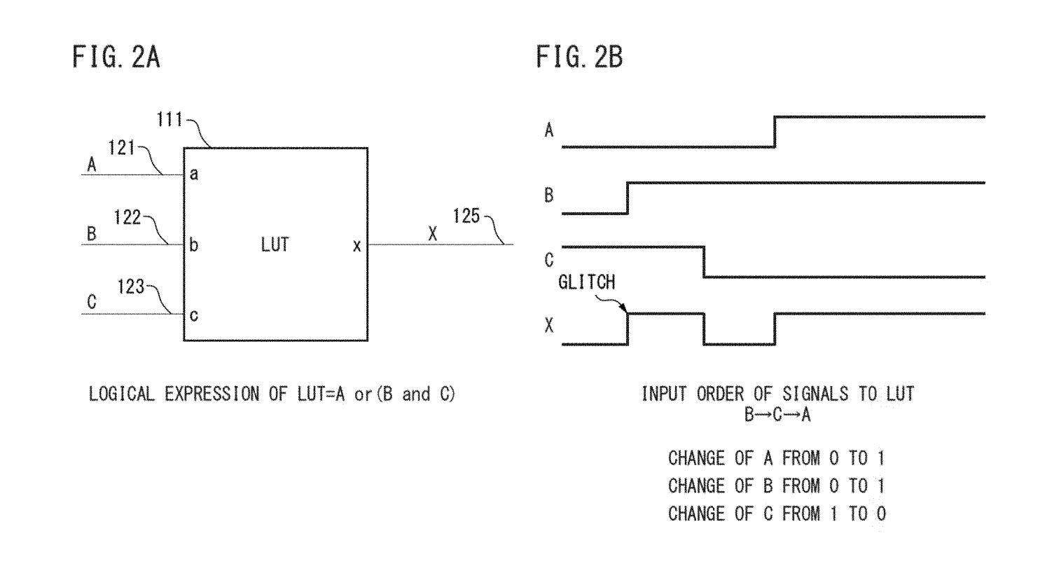

FIG. 2A is a diagram illustrating the first LUT 111 and FIG. 2B is a diagram illustrating an example of a timing chart of input/output signals of the first LUT 111. The logical expression of the first LUT 111 is X=A or (B and C). A is a first input signal that is input to the first input port a, B is a second input signal that is input to the second input port b, and C is a third input signal that is input to the third input port c. The second input signal that is input to the second input port b, the third input signal that is input to the third input port c, and the first input signal that is input to the first input port a are input in this order to the first LUT 111. The first input signal A and the second input signal B transit from the L level to the H level and the third input signal C transits from the H level to the L level.

In the first LUT 111, during the period from when the second input signal B transits from the L level to the H level until the third input signal C transits from the H level to the L level, an output signal X transits to the H level and a glitch having a short width occurs. The glitch having occurred in the output signal X of the first LUT 111 sequentially propagates to the second LUT 112, to the third LUT 113, and to the seventh flip-flop 107.

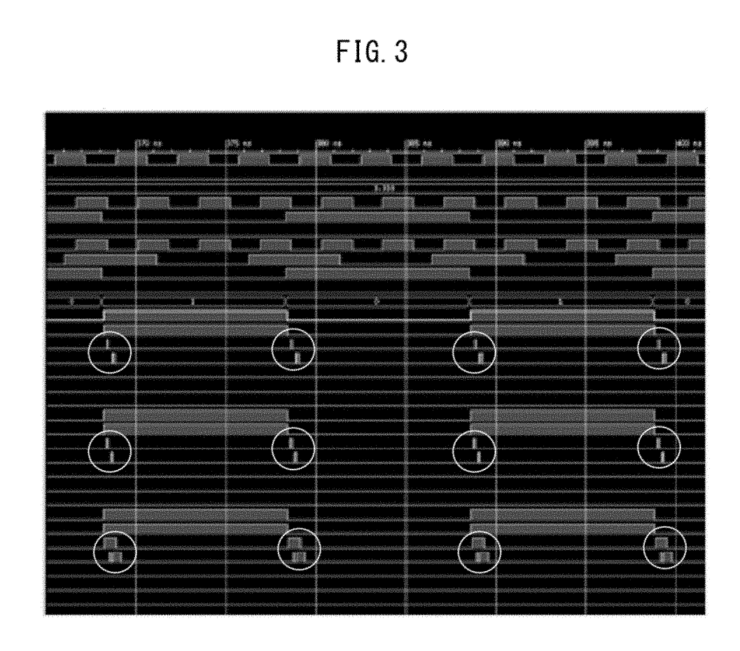

FIG. 3 is a diagram illustrating an example of simulation results in which glitches occur. In FIG. 3, a glitch is encircled by a circle symbol.

When a glitch occurs, the number of times the output signal of the LUT transits per unit time, i.e., a frequency F of the output signal of the LUT increases. When the frequency F of the output signal of the LUT increases, dynamic current consumption P (=(½)×F×Cₚ×V², Cₚ: average load capacitance, V: power source voltage) increases. In the example illustrated in FIGS. 2A and 2B, when no glitch occurs, the output signal X of the first LUT 111 transits from the L level to the H level per unit time. However, when one glitch occurs, the output signal X of the first LUT 111 transits from the L level to the H level, a transition from the H level to the L level, and a transition from the L level to the H level per unit time, and therefore the dynamic current consumption P of the first LUT 111 triples.

In the example illustrated in FIG. 3, if the occurrence of a glitch is prevented, the power consumption of the FPGA is reduced from 12.24 W by 5.9%, i.e., 11.52 W. By suppressing an increase in the dynamic power consumption due to a glitch in a combinational circuit (LUT), the dynamic power consumption of the FPGA is reduced.

### Configuration and Function of Programmable Logic Device Designing Apparatus According to First Embodiment

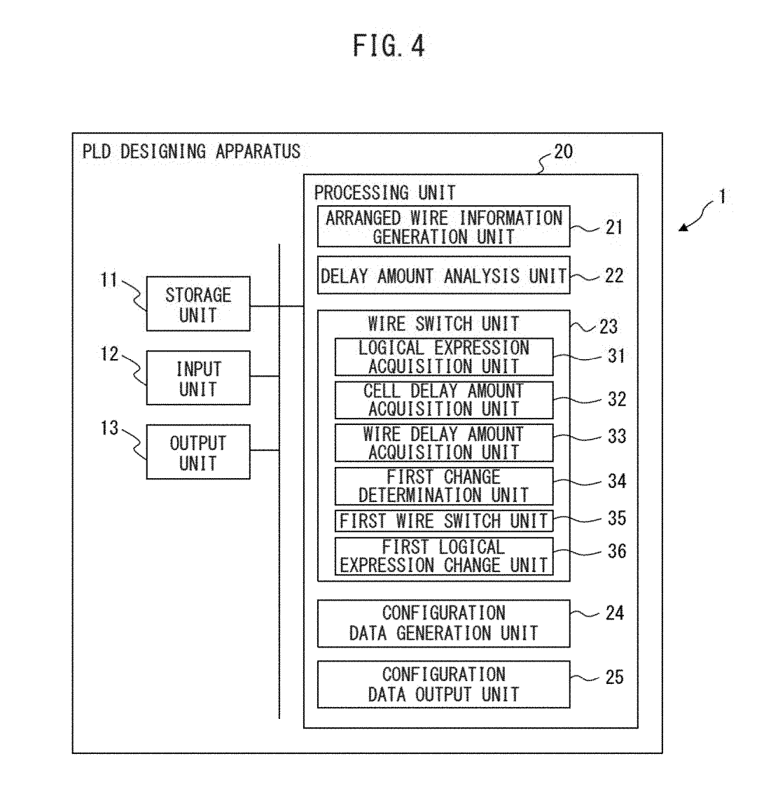

FIG. 4 is a block diagram of a programmable logic device designing apparatus (hereinafter, also referred to as PLD designing apparatus) according to a first embodiment.

A PLD designing apparatus 1 includes a storage unit 11, an input unit 12, an output unit 13, and a processing unit 20. The PLD designing apparatus 1 generates configuration data including arranged wire information on an FPGA by using RTL data and timing constraints data. The PLD designing apparatus 1 changes the arranged wire information in order to exchange the input ports of the connection destinations of the wires connected to at least two input ports of the LUT so as to minimize the number of glitches in the LUT.

The storage unit 11 includes at least one of a magnetic tape device, a magnetic disk device, or an optical disk device. The storage unit 11 stores an operating system program, driver programs, application programs, data, etc., which are used for processing by the processing unit 20. For example, the storage unit 11 stores, as an application program, a configuration data generation program or the like for causing the processing unit 20 to perform processing to generate FPGA configuration data. The configuration data generation program in the storage unit 11 may be installed by using a publicly known setup program or the like from, for example, a computer readable portable storage medium, such as a CD-ROM and a DVD-ROM.

Further, the storage unit 11 stores RTL data and timing constraints data used for the configuration data generation processing. The RTL data is data representing the logic of the logic circuit that is mounted on the FPGA. The timing constraints data is an SDC (Synopsys Design Constraints) file as an example, and specifies timing constraints of the logic circuit that is mounted on the FPGA. Further, the storage unit 11 stores an input port change table showing a relationship between the logical expression of the LUT and the input order of input signals that are input to the LUT, which minimizes the number of glitches in the LUT. Furthermore, the storage unit 11 may temporarily store temporary data relating to predetermined processing.

The input unit 12 may be any device as long as the device input data, and is, for example, a touch panel, a key button, etc. An operator may input characters, figures, symbols, etc., by using the input unit 12. The input unit 12 generates a signal corresponding to the operation indicated by an operator. Then, the generated signal is supplied to the processing unit 20 as instructions of the operator.

The output unit 13 may be any device as long as the device displays a video, an image, etc., and is, for example, a liquid crystal display, an EL (Electro-Luminescence) display, etc. The output unit 13 displays a video corresponding to video data supplied from the processing unit 20, an image corresponding to image data, etc. Further, the output unit 13 may be an output apparatus that prints a video, an image, a character, etc., on a display medium, such as paper.

The processing unit 20 has one or a plurality of processors and peripheral circuits thereof. The processing unit 20 is configured to generally control the total operation of the PLD designing apparatus 1, and is, for example, a CPU. The processing unit 20 performs processing based on programs (driver program, operating system program, application program, etc.) stored in the storage unit 11. Further, the processing unit 20 may execute a plurality of programs (application program or the like) parallelly.

The processing unit 20 has an arranged wire information generation unit 21, a delay amount analysis unit 22, a wire switch unit 23, a configuration data generation unit 24, and a configuration data output unit 25. The wire switch unit 23 has a logical expression acquisition unit 31, a cell delay amount acquisition unit 32, a wire delay amount acquisition unit 33, a first change determination unit 34, a first wire switch unit 35, and a first logical expression change unit 36. Each of these units is a function module that is implemented by a program executed by a processor included in the processing unit 20. Alternatively, each of these units may be packaged in the PLD designing apparatus as firmware.

### Operation of Programmable Logic Device Designing Apparatus According to First Embodiment

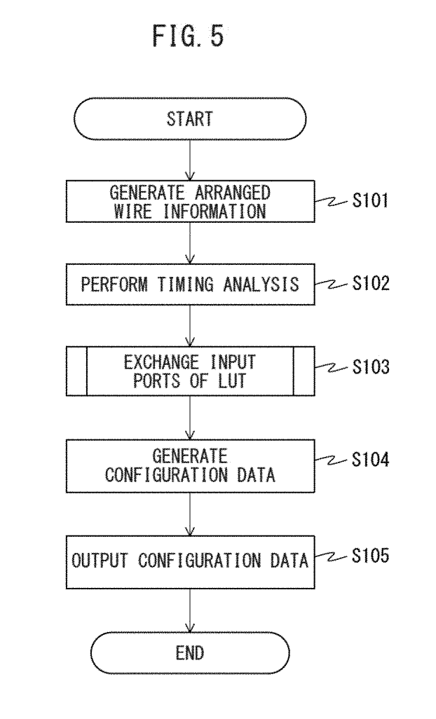

FIG. 5 is a flowchart of configuration data generation processing by the PLD designing apparatus 1. The configuration data generation processing is performed mainly by the processing unit 20 in cooperation with each element of the PLD designing apparatus 1 based on a program stored in advance in the storage unit 11.

First, the arranged wire information generation unit 21 generates a net list by performing logical combination using the RTL data and the timing constraints data stored in the storage unit 11, generates arranged wire information from the generated net list, and stores the arranged wire information in the storage unit 11 (S101). Next, the delay amount analysis unit 22 performs a timing analysis of the arranged wire information by using the arranged wire information generated by the arranged wire information generation unit 21 and the timing constraints data (S102). Next, the wire switch unit 23 changes the arranged wire information so that the input ports of the connection destinations of the wires connected to at least two input ports of the LUT and the logical expressions are exchanged so as to minimize the number of glitches in the LUT (S103). Next, the configuration data generation unit 24 generates configuration data including the arranged wire information generated by the arranged wire information generation unit 21 (S104). Then, the configuration data output unit 25 outputs the configuration data generated by the configuration data generation unit 24 to the storage unit 11 (S105).

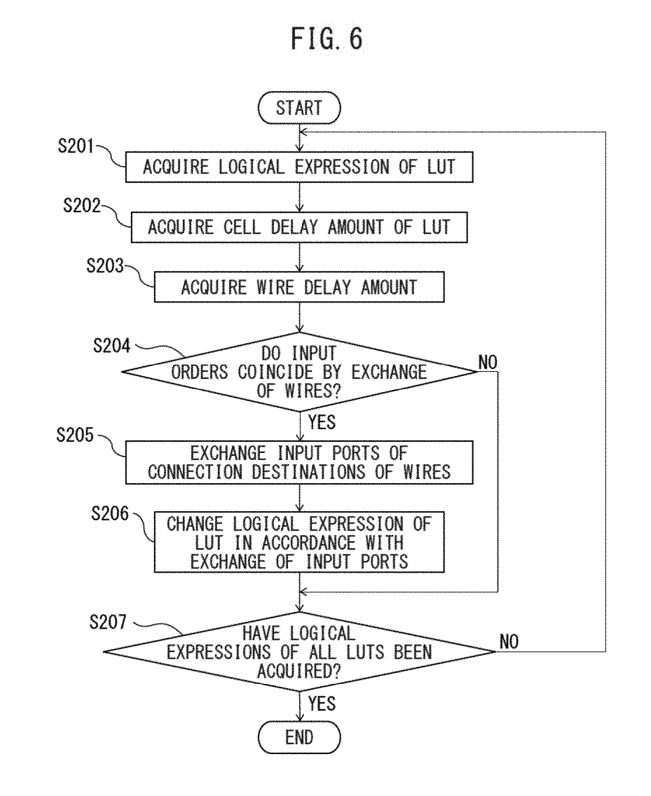

FIG. 6 is a flowchart illustrating a more detailed processing flow of the processing at S103.

First, the logical expression acquisition unit 31 acquires the logical expression of the first LUT from the arranged wire information stored in the storage unit (S201). Next, the cell delay amount acquisition unit 32 acquires the cell delay amount of the first LUT from the arranged wire information stored in the storage unit (S202). The cell delay amount of the first LUT includes the delay amount from each of the plurality of input ports to the output port. Next, the wire delay amount acquisition unit 33 acquires the wire delay amount of each of the wires connected to the input ports of the first LUT from the arranged wire information stored in the storage unit 11 (S203). Next, the first change determination unit 34 determines whether the input order of the input signals that are input to the first LUT coincides with the input order stored in the input port change table when the wires are exchanged from the wire delay amount and the cell delay amount of the first LUT (S204). In the case where it is determined that the input order of the input signals of the first LUT coincides with the input order stored in the input port change table when the wires are exchanged (S204), the processing proceeds to S205. Next, the first wire switch unit 35 exchanges the input ports of the connection destinations of the wires connected to the input ports of the first LUT so that the input order of the input signals of the first LUT coincides with the input order corresponding to the logical expression of the first LUT stored in the input port change table (S205). The first wire switch unit 35 changes the arranged wire information stored in the storage unit 11 so that the input ports of the connection destinations of the wires connected to the input ports of the first LUT are exchanged (S206). Next, the first logical expression change unit 36 changes the arranged wire information so that the logical expression of the first LUT is changed in accordance with the exchange of the input ports of the connection destinations of the wires, and the processing proceeds to S207. On the other hand, in the case where it is determined that the input order of the input signals that are input to the first LUT does not coincide with the input order stored in the input port change table (S204), the processing proceeds to S207.

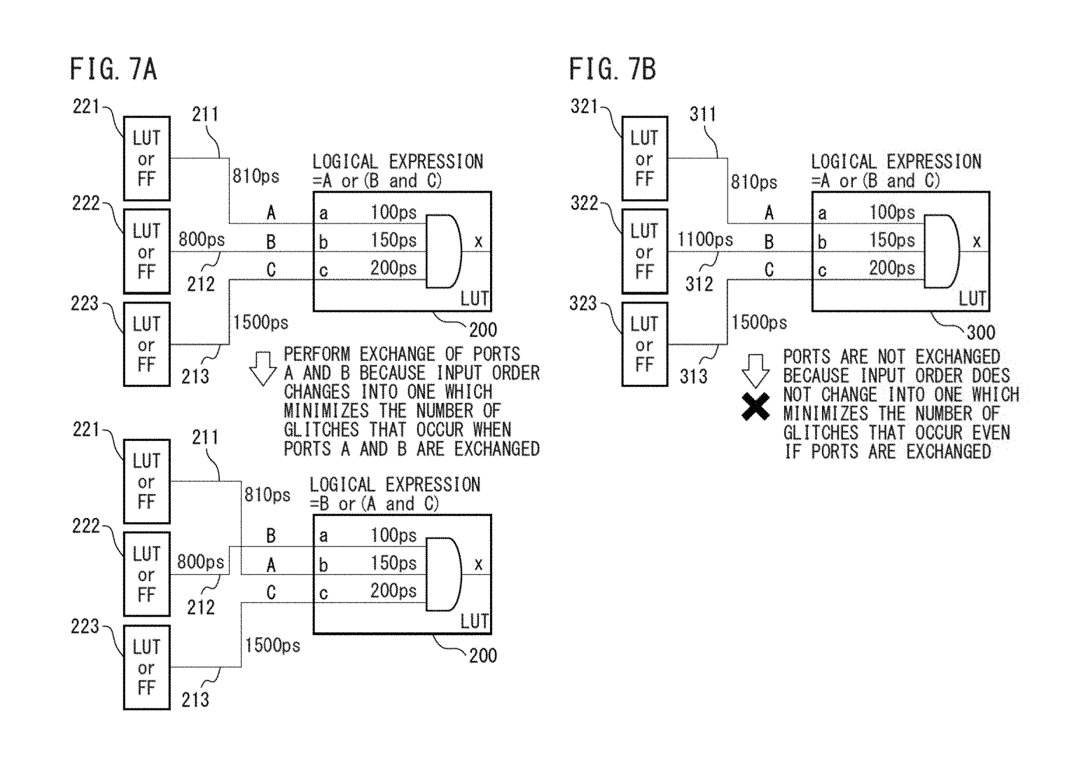

FIG. 7A is a diagram illustrating an example of the first LUT and FIG. 7B is a diagram illustrating another example of the first LUT.

A first LUT 200 illustrated in FIG. 7A is a combinational circuit having a first input port a, a second input port b, a third input port c, and an output port x, and configured to perform the arithmetic operation of a logical expression (X=A or (B and C)). A indicates a first input signal that is input to the first input port a, B indicates a second input signal that is input to the second input port b, and C indicates a third input signal that is input to the third input port c. X indicates an output signal that is output from the output port x. The first input signal is input from a first output sell 221 to the first input port a via a first wire 211 and to the second input port b, the second input signal is input from a second output cell 222 via a second wire 212. The third input signal is input from a third output cell 223 to the third input port c via a third wire 213.

First, the logical expression acquisition unit 31 acquires the logical expression of the first LUT 200 from the arranged wire information stored in the storage unit 11 (S201). The logical expression of the first LUT 200 is X=A or (B and C). Next, the cell delay amount acquisition unit 32 acquires the cell delay amount of the first LUT 200 from the arranged wire information stored in the storage unit 11 (S202). A first cell delay amount from the first input port a to the output terminal of the first LUT 200 is 100 ps and a second cell delay amount from the second input port b to the output terminal of the first LUT 200 is 150 ps. A third cell delay amount from the third input port c to the output terminal of the first LUT 200 is 200 ps. Next, the wire delay amount acquisition unit 33 acquires the wire delay amount of each of the wires connected to the input ports of the first LUT 200 from the arranged wire information stored in the storage unit 11 (S203). A first wire delay amount of the first wire 211 is 810 ps, a second wire delay amount of the second wire 212 is 800 ps, and a third wire delay amount of the third wire 213 is 1,500 ps.

Next, the first change determination unit 34 determines whether the input order of the input signals coincides with the input order stored in the input port change table when the first wire 211 to the third wire 213 are exchanged (S204).

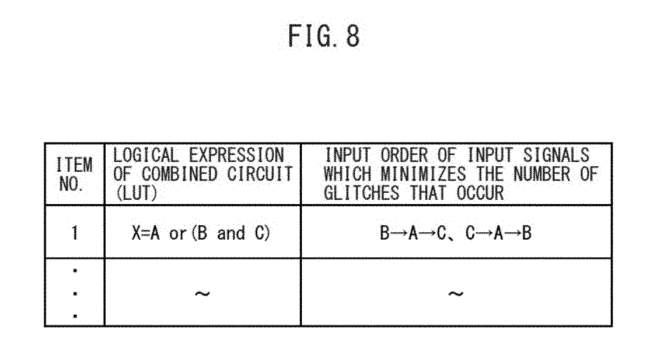

FIG. 8 is a diagram illustrating an input port change table.

In the input port change table, a relationship between the logical expression of a combinational circuit of a so-called complex gate, such as the logical expression (X=A or (B and C), and the input order of the input signals which minimizes the number of glitches in the logical expression is shown.

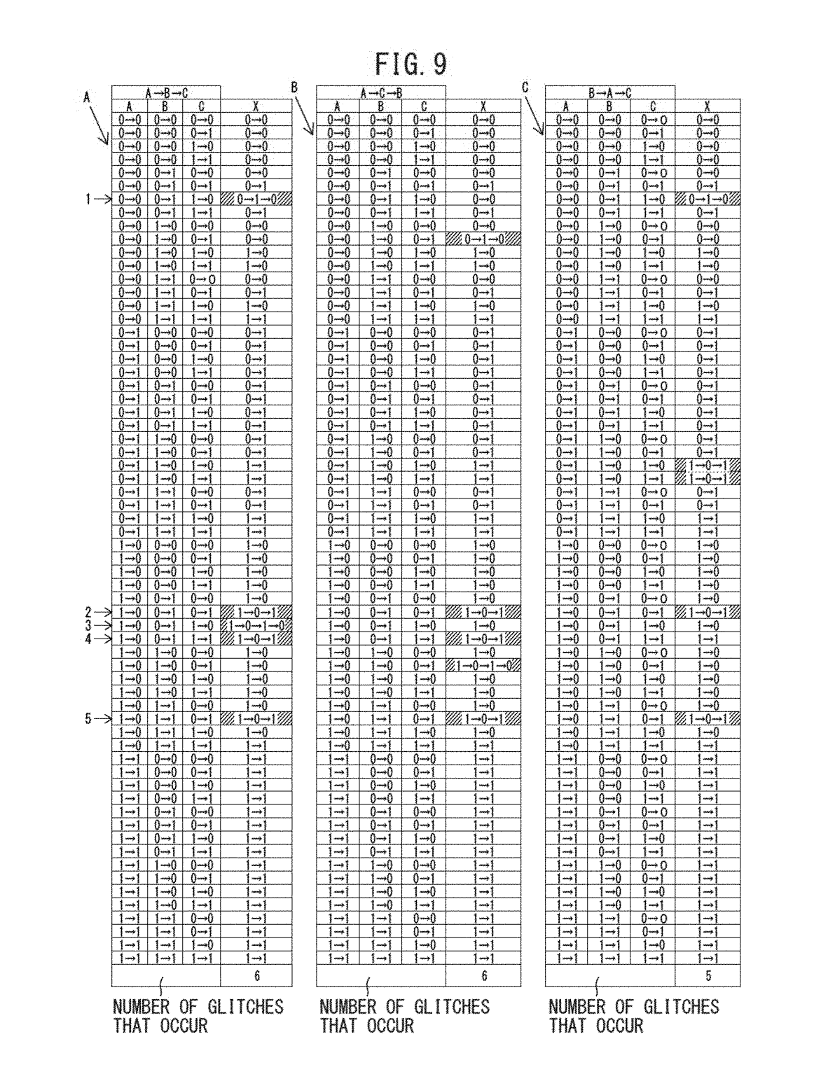

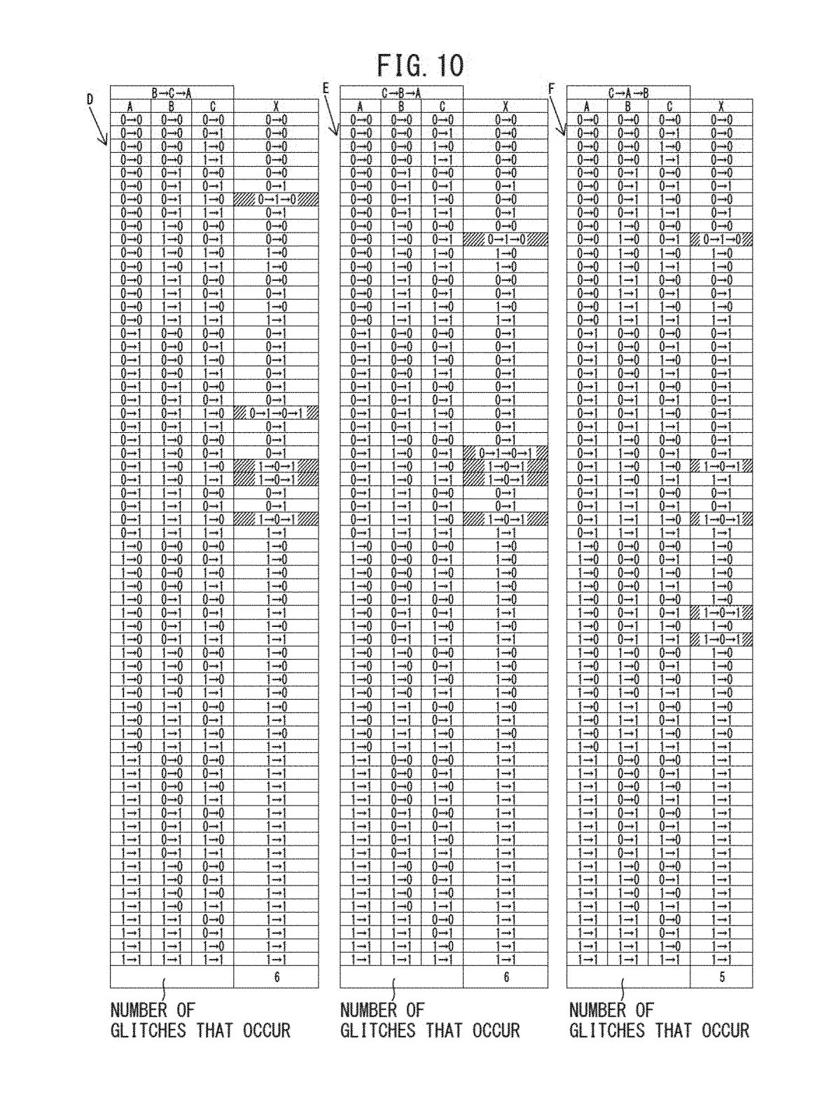

FIG. 9 is a table (Part 1) that is used in the processing to determine the input order of the input signals which minimizes the number of glitches in the logical expression (X=A or (B and C)). FIG. 10 is a table (Part 2) that is used in the processing to determine the input order of the input signals which minimizes the number of glitches in the logical expression (X=A or (B and C)). A table indicated by an arrow A in FIG. 9 shows the case where the signal value transits in the order of the first input signal A, the second input signal B, and the third input signal C. A table indicated by an arrow B in FIG. 9 shows the case where the signal value transits in the order of the first input signal A, the third input signal C, and the second input signal B. A table indicated by an arrow C in FIG. 9 shows the case where the signal value transits in the order of the second input signal B, the first input signal A, and the third input signal C. A table indicated by an arrow D in FIG. 10 shows the case where the signal value transits in the order of the second input signal B, the third input signal C, and the first input signal A. A table indicated by an arrow E in FIG. 10 shows the case where the signal value transits in the order of the third input signal C, the second input signal B, and the first input signal A. A table indicated by an arrow F in FIG. 10 shows the case where the signal value transits in the order of the third input signal C, the first input signal A, and the second input signal B. In the tables illustrated in FIGS. 9 and 10, the row in which the field of the output signal X is hatched indicates the input order that causes a glitch to occur.

An operator or an arithmetic and logic unit, not illustrated, performs an arithmetic operation as to whether a glitch occurs when the first input signal A to the third input signal C transit in each input order in the tables illustrated in FIGS. 9 and 10. In the transitions of the signal value indicated by arrows 1 to 5, respectively, in the table indicated by the arrow A in FIG. 9, a glitch occurs, and in the transition of the signal value indicated by the arrow 3, a glitch occurs twice. In the four transitions, a glitch occurs once and in the one transition of the signal value, a glitch occurs twice, and therefore the number of glitches that occur by the input order shown in the table indicated by the arrow A in FIG. 9 is six.

Similarly, the number of glitches that occur by the input order indicated by the arrow B in FIG. 9 is six and the number of glitches that occur by the input order indicated by the arrow C in FIG. 9 is five. Further, the number of glitches that occur by the input orders indicated by the arrows D and E in FIG. 10 is six and the number of glitches that occur by the input order indicated by the arrow F in FIG. 10 is five.

By the input order “the second input signal B→the first input signal A→the third input signal C” indicated by the arrow C in FIG. 9 and the input order “the third input signal C→the first input signal A→the second input signal B” indicated by the arrow F in FIG. 10, the number of glitches is five, which is smaller than that by the other input orders. The input orders “the second input signal B→the first input signal A→the third input signal C” and “the third input signal C→the first input signal A→the second input signal B” are registered in the input port change table in correspondence to the logical expression (X=A or (B and C)).

The input port change table stores a relationship between the logical expression of a combinational circuit of another complex gate, such as the logical expression (X=A and (B or C)), and the input order of the input signals which minimizes the number of glitches in the logical expression.

The first change determination unit 34 determines that the input order of the input signals coincides with the input order stored in the input port change table by exchanging the connection destinations of the first wire 211 connected to the first input port a and the second wire 212 connected to the second input port b (S204).

Next, the first wire switch unit 35 exchanges the connection destinations of the first wire 211 connected to the first input port a and the second wire 212 connected to the second input port b (S205). When the connection destinations of the first wire 211 connected to the first input port a and the second wire 212 connected to the second input port b are exchanged, the total delay amount of the first input signal A is the sum of the first wire delay amount 810 ps and the second cell delay amount 150 ps, i.e., 960 ps. On the other hand, the total delay amount of the second input signal B is the sum of the second wire delay amount 800 ps and the first cell delay amount 100 ps, i.e., 900 ps. Further, the total delay amount of the third input signal C is the sum of the third wire delay amount 1,500 ps and the third cell delay amount 200 ps, i.e., 1,700 ps.

Next, the first logical expression change unit 36 changes the arranged wire information so that the logical expression of the first LUT 200 is changed in accordance with the exchange of the input ports of the connection destinations of the wires (S206). In other words, the first logical expression change unit 36 changes the logical expression of the first LUT 200 from the logical expression (X=A or (B and C)) into the logical expression (X=B or (A and C)).

By the processing unit 20 performing the processing at S103, the input order becomes the order of the first input signal A via the second input port b, the second input signal B via the first input port a, and the third input signal C via the third input port. The input order that becomes the order of the first input signal via the second input port b, the second input signal via the first input port a, and the third input signal via the third input port is the input order that minimizes the number of glitches. By the processing unit 20 performing the processing at S103, the number of glitches is minimized and the occurrence of the dynamic power consumption resulting from a glitch may be suppressed to the minimum.

A first LUT 300 illustrated in FIG. 7B is a combinational circuit having a first input port a, a second input port b, a third input port c, and an output port x and configured to perform an arithmetic operation of the logical expression (X=A or (B and C)) like the first LUT 200 illustrated in FIG. 7A. A first input signal A is input from a first output cell 321 to the first input port a via a first wire 311 and to the second input port b, a second input signal B is input from a second output cell 322 via a second wire 312. A third input signal C is input from a third output cell 323 to the third input port c via a first wire 313.

First, the logical expression acquisition unit 31 acquires the logical expression of the first LUT 300 from the arranged wire information stored in the storage unit 11 (S201). The logical expression of the first LUT 300 is X=A or (B and C). Next, the cell delay amount acquisition unit 32 acquires the cell delay amount of the first LUT 300 from the arranged wire information stored in the storage unit 11 (S202). A first cell delay amount from the first input port a to the output terminal of the first LUT 300 is 100 ps and a second cell delay amount from the second input port b to the output terminal of the first LUT 300 is 150 ps. A third cell delay amount from the third input port c to the output terminal of the first LUT 300 is 200 ps. Next, the wire delay amount acquisition unit 33 acquires the wire delay amount of each of the wires connected to the input ports of the first LUT 300 from the arranged wire information stored in the storage unit 11 (S203). A first wire delay amount of the first wire 311 is 810 ps, a second wire delay amount of the second wire 312 is 1,100 ps, and a third wire delay amount of the third wire 313 is 1,500 ps,

Next, the first change determination unit 34 determines whether the input order of the input signals coincides with the input order stored in the input port change table when the first wire 311 to the third wire 313 are exchanged (S204). The first change determination unit 34 determines that the input order of the input signals does not coincide with the input order stored in the input port change table when the first wire 311 to the third wire 313 are exchanged (S204) and the processing proceeds to S207.

At S207, the logical expression acquisition unit 31 determines whether the logical expressions of all the LUTs included in the arranged wire information have been acquired (S207). Until the logical expression acquisition unit 31 determines that the logical expressions of all the LUTs included in the arranged wire information have been acquired, the processing at S201 to S207 is repeated. Each time the processing at S201 to S207 is performed, it is determined whether an input port of the connection destination of the wire connected to any one of the input ports of the LUT included in the arranged wire information is exchanged with another (S204). When it is determined that the input order of the input signals of the LUT coincides with the input order shown in the input port change table (S204), the wires connected to the input ports are exchanged so that the input order of the input signals of the LUT coincides with the input order shown in the input port change table (S205). Next, the logical expression of the LUT is changed in accordance with the exchange of the input ports of the connection destinations of the wires (S206). Then, when the logical expression acquisition unit 31 determines that the logical expressions of all the LUTs included in the arranged wire information have been acquired (S207), the processing at S103 is terminated.

### Configuration and Function of Programmable Logic Device Designing Apparatus According to Second Embodiment

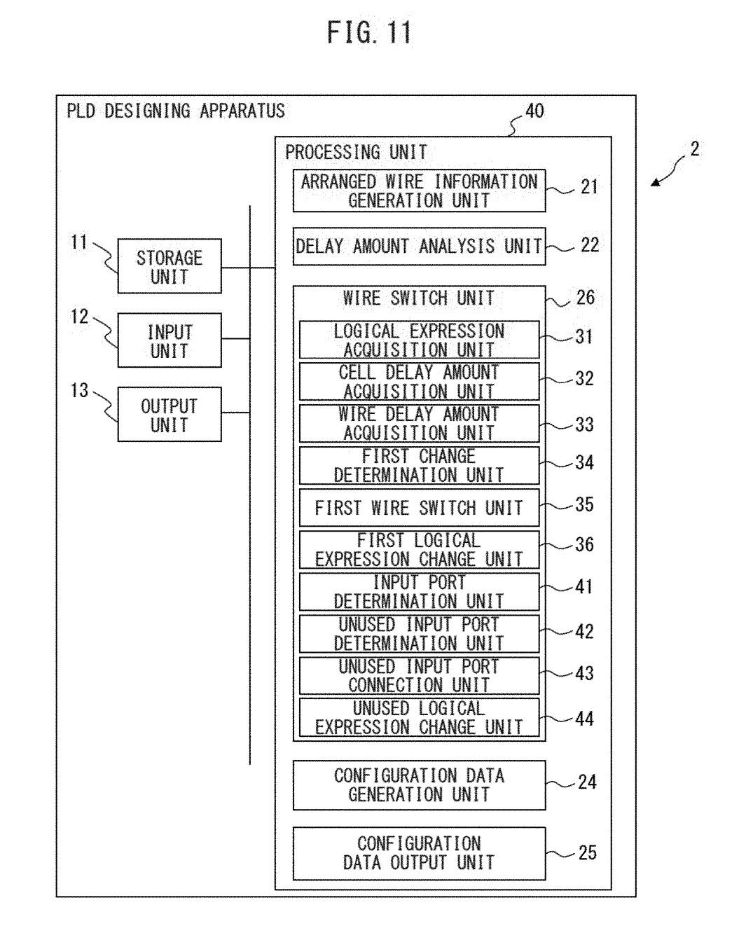

FIG. 11 is a block diagram of a PLD designing apparatus according to a second embodiment.

A PLD designing apparatus 2 differs from the PLD designing apparatus 1 in that a processing unit 40 having a wire switch unit 26 in place of the wire switch unit 23 is arranged in place of the processing unit 20. The wire switch unit 26 differs from the wire switch unit 23 in further having an input port determination unit 41, an unused input port determination unit 42, an unused input port connection unit 43, and an unused logical expression change unit 44. The configurations and the functions of the components of the PLD designing apparatus 2 other than the input port determination unit 41, the unused input port determination unit 42, the unused input port connection unit 43, and the unused logical expression change unit 44 are the same as the configurations and the functions of the components of the PLD designing apparatus 1 to which the same symbols are attached. Thus, detailed explanation of the components of the PLD designing apparatus 2 other than the unused input port connection unit 43 and the unused logical expression change unit 44 is omitted here.

### Operation of Programmable Logic Device Designing Apparatus According to Second Embodiment

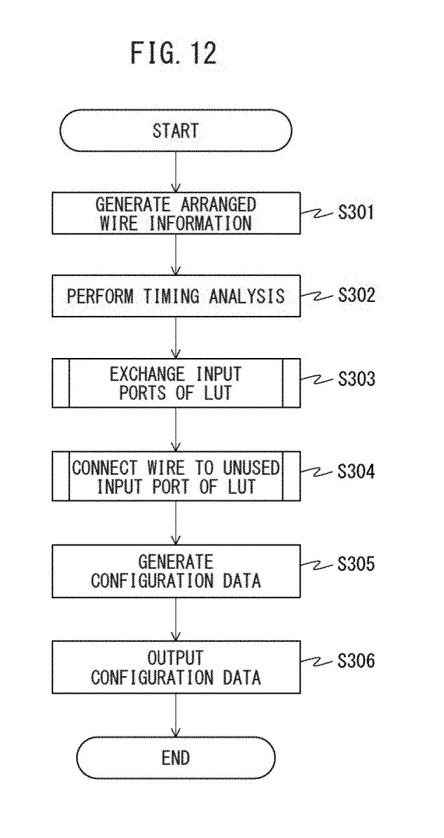

FIG. 12 is a flowchart of configuration data generation processing by the PLD designing apparatus 2. The configuration data generation processing is performed mainly by the processing unit 40 in cooperation with each element of the PLD designing apparatus 2 based on a program stored in advance in the storage unit 11.

The processing at S301 to S303 and S305 to S306 is the same as the processing at S101 to S105, and therefore detailed explanation is omitted here.

At S304, the wire switch unit 26 changes arranged wire information so that the number of glitches in the LUT is minimized by connecting any of the wires connected to the input ports to an unused input port to which no input signal is input (S304).

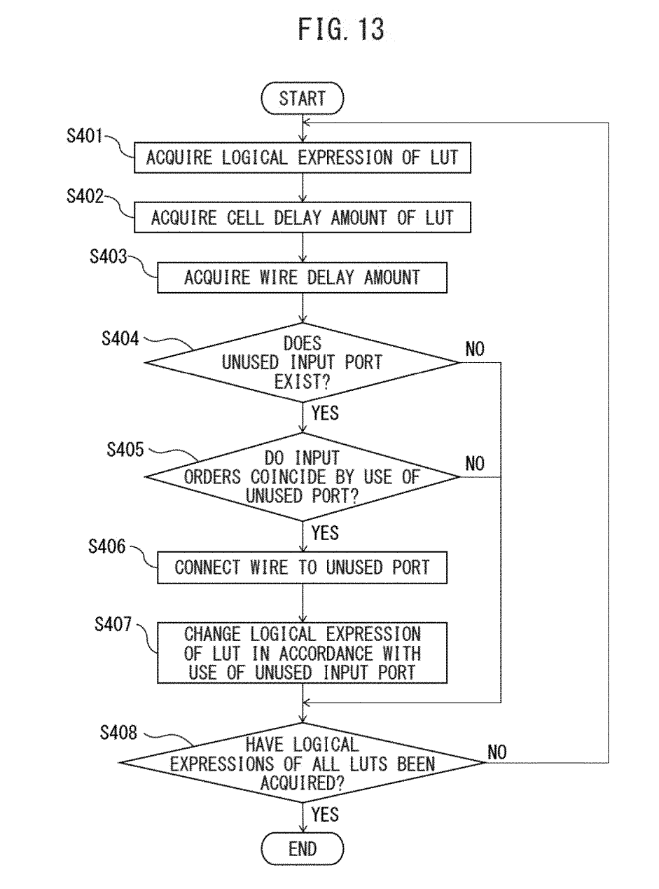

FIG. 13 is a flowchart illustrating a more detailed processing flow of the processing at S304.

First, the logical expression acquisition unit 31 acquires the logical expression of any one of the LUTs in which the input port of the connection destination of the wire has not been changed by the processing at S303 from the arranged wire information stored in the storage unit 11 (S401). Next, the cell delay amount acquisition unit 32 acquires the cell delay amount of the LUT whose logical expression has been acquired by the processing at S401 from the arranged wire information stored in the storage unit 11 (S402). Next, the wire delay amount acquisition unit 33 acquires the wire delay amount of each of the wires connected to the input ports of the LUT whose logical expression has been acquired by the processing at S401 from the arranged wire information stored in the storage unit 11 (S403). Next, the input port determination unit 41 determines whether there is an unused input port to which no input signal is input in the LUT whose logical expression has been acquired by the processing at S401 (S404). When the number of input ports of the LUT is four and the logical expression of the LUT is a combinational circuit of three inputs, there is one unused input port, which is an input port that is not used.

Next, the unused input port determination unit 42 determines whether the input order of the input signals that are input to the LUT coincides with the input port stored in the input port change table when any one of the wires is connected to the unused input port (S405). When it is determined that the input order of the input signals that are input to the LUT coincides with the input port stored in the input port change table (S405), the processing proceeds to S406. The unused input port connection unit 43 connects any one of the wires to the unused input port so that the input order of the input signals of the LUT coincides with the input order corresponding to the logical expression of the LUT stored in the input port change table. (S406). The unused input port connection unit 43 changes the arranged wire information stored in the storage unit 11 so that any one of the wires is connected to the unused input port so that the input order coincides with the input order corresponding to the logical expression of the LUT stored in the input port change table. Next, the unused logical expression change unit 44 changes the arranged wire information so that the logical expression of the LUT is changed in accordance with the use of the unused input port. On the other hand, when it is determined that the input order of the input signals that are input to the LUT does not coincide with the input order stored in the input port change table (S405), the processing proceeds to S408.

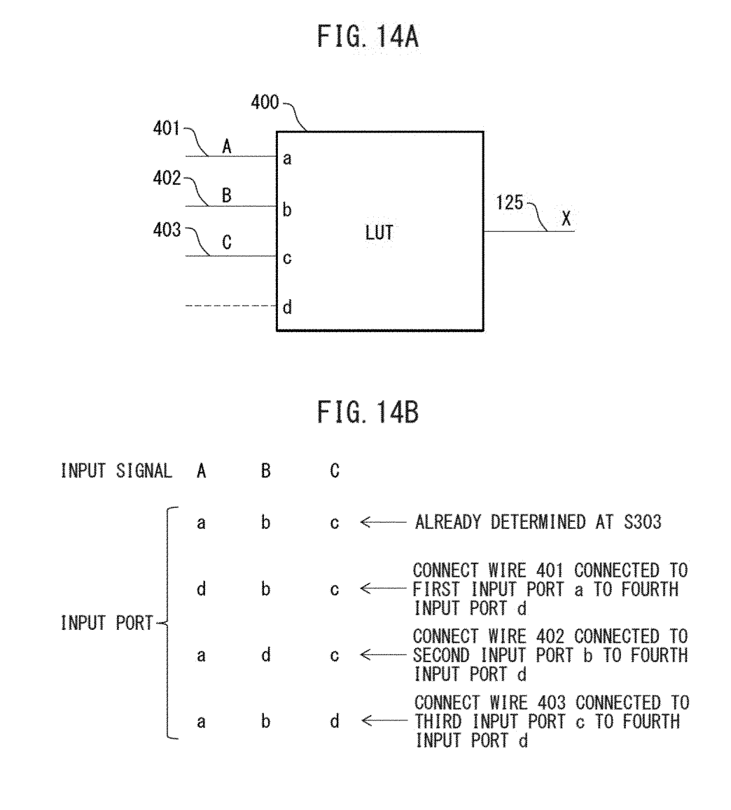

FIG. 14A is a diagram illustrating an LUT in which input signals are input to a first input port a to a third input port c and a fourth input port d is an unused input port, and FIG. 14B is a diagram illustrating a state where the processing at S405 is performed in the LUT illustrated in FIG. 14A.

A first input signal A is input to the first input port a of an LUT 400 via a first wire 401 and a second input signal B is input to the second input port b of the LUT 400 via a second wire 402. Further, a third input signal C is input to the third input port c of the LUT 400 via a third wire 403.

The unused input port determination unit 42 determines whether the input order of the input signals that are input to the LUT coincides with the input port stored in the input port change table when any one of the first wire 401 to the third wire 403 is connected to the fourth input port d (S405). When it is determined that the input order of the input signals coincides with the input order shown in the input port change table by the use of the fourth input port d (S405), the unused input port connection unit 43 connects the wire to the unused input port so that the input order coincides with the input order shown in the input port change table (S406). Next, the unused logical expression change unit 44 changes the logical expression of the LUT in accordance with the connection of the wire to the fourth input port d (S407).

At S408, the logical expression acquisition unit 31 determines whether the logical expressions of all the LUTs whose input port of the connection destination of the wire has not been changed by the processing at S303 have been acquired (S408). Until the logical expression acquisition unit 31 determines that the logical expressions of all the LUTs included in the arranged wire information have been acquired, the processing at S401 to S408 is repeated. Each time the processing at S401 to S408 is performed, whether the input order of the input signals that are input to the LUT coincides with the input port stored in the input port change table when any one of the wires is connected to the unused input port is determined (S405). When it is determined that the input order by the use of the unused input port coincides with the input port shown in the input port change table, the wire is connected to the unused input port so that the input order by the use of the unused input port coincides with the input order shown in the input port change table (S406). Next, the logical expression of the LUT is changed in accordance with the use of the unused input port (S407). Then, when the logical expression acquisition unit 31 determines that the logical expressions of all the LUTs whose input port of the connection destination of the wire has not been changed by the processing at S303 have been acquired (S408), the processing at S304 is terminated.

### Configuration and Function of Programmable Logic Device Designing Apparatus According to Third Embodiment

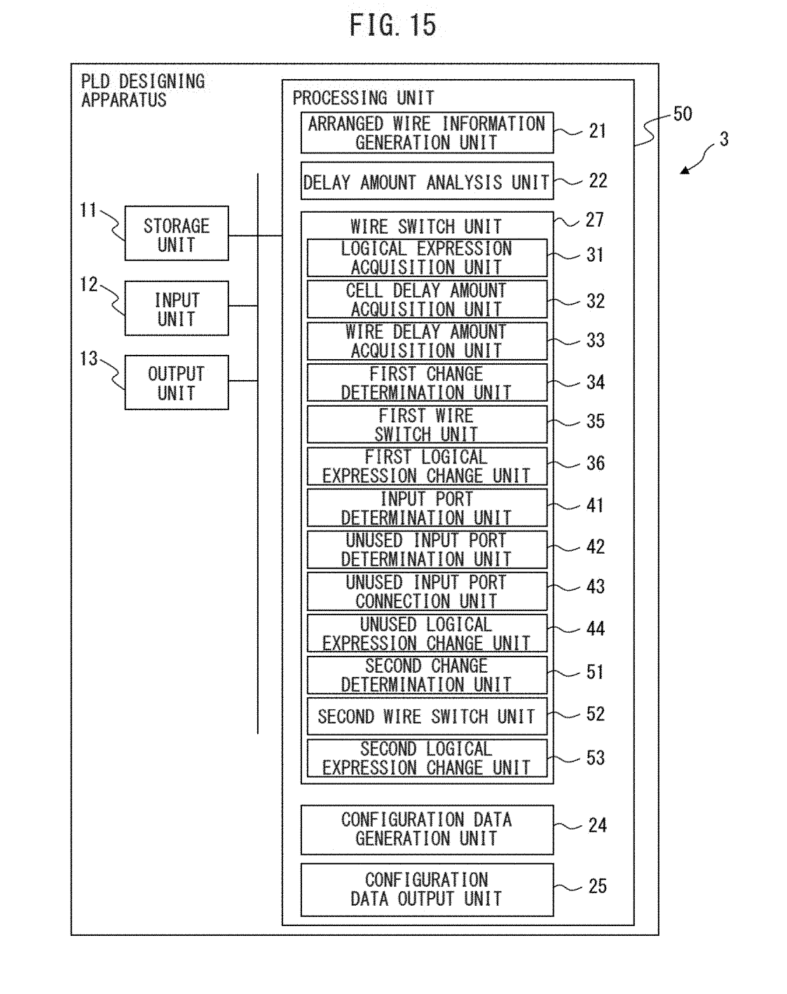

FIG. 15 is a block diagram of a PLD designing apparatus according to a third embodiment.

A PLD designing apparatus 3 differs from the PLD designing apparatus 2 in that a processing unit 50 having a wire switch unit 27 in place of the wire switch unit 26 is arranged in place of the processing unit 40. The wire switch unit 27 differs from the wire switch unit 26 in further having a second change determination unit 51, a second wire switch unit 52, and a second logical expression change unit 53. The configurations and the functions of the components of the PLD designing apparatus 3 other than the second change determination unit 51, the second wire switch unit 52, and the second logical expression change unit 53 are the same as the configurations and the functions of the components of the PLD designing apparatus 2 to which the same symbols are attached, and therefore detailed explanation is omitted here.

### Operation of Programmable Logic Device Designing Apparatus According to Third Embodiment

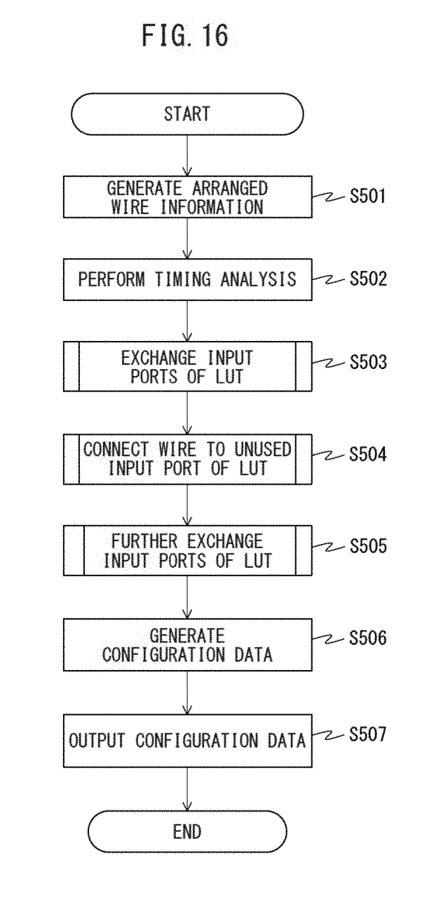

FIG. 16 is a flowchart of configuration data generation processing by the PLD designing apparatus 3. The configuration data generation processing is performed mainly by the processing unit 50 in cooperation with each element of the PLD designing apparatus 3 based on a program stored in advance in the storage unit 11.

The processing at S501 to S504 and S506 to S507 is the same as the processing at S301 to S306, and therefore detailed explanation is omitted here.

At S505, the input ports of the LUT of the connection destinations of the wires are exchanged so that a glitch width, which is a pulse width of a glitch that occurs from the LUT, becomes less than or equal to a predetermined threshold value when the wires are exchanged based on the wire delay amount and the cell delay amount of the LUT (S505). The predetermined threshold value is determined from the operating speed of a transistor forming the LUT. The predetermined threshold value corresponds to a period during which the transistor forming the LUT does not react when the glitch width is less than or equal to the threshold value and the LUT does not cause a glitch to occur.

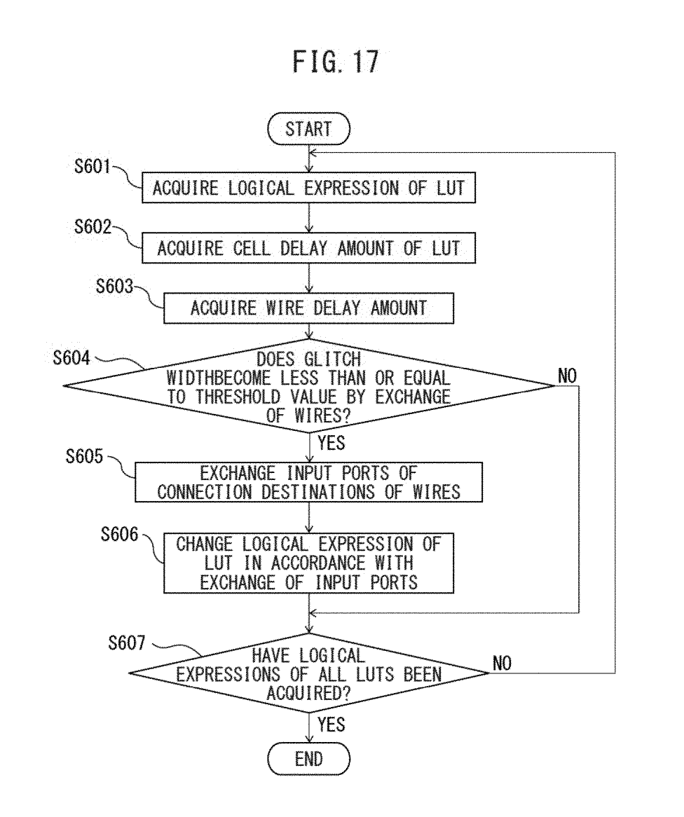

FIG. 17 is a flowchart illustrating a more detailed processing flow of the processing at S505.

First, the logical expression acquisition unit 31 acquires the logical expression of any one of LUTs whose wires have not been connected to the unused input port by the processing at S504 from the arranged wire information stored in the storage unit 11 (S601). Next, the cell delay amount acquisition unit 32 acquires the cell delay amount of the LUT whose logical expression has been acquired by the processing at S601 from the arranged wire information stored in the storage unit 11 (S602). Next, the wire delay amount acquisition unit 33 acquires the wire delay amount of each of the wires connected to the input ports of the LUT whose logical expression has been acquired by the processing at S601 from the arranged wire information stored in the storage unit 11 (S603). Next, the second change determination unit 51 determines whether the width of a glitch that occurs from the LUT becomes less than or equal to a predetermined threshold value when the wires are exchanged from the wire delay amount and the cell delay amount of the first LUT (S604). When the width of a glitch that occurs from the LUT becomes less than or equal to the predetermined value when the wires are exchanged (S604), the processing proceeds to S605. Next, the second wire switch unit 52 exchanges the input ports of the connection destinations of the wires connected to the input ports of the LUT so that the width of a glitch that occurs from the LUT becomes less than or equal to the predetermined threshold value (S605). The second wire switch unit 52 changes the arranged wire information stored in the storage unit 11 so that the input ports of the connection destinations of the wires connected to the input ports of the LUT are exchanged. Next, the second logical expression change unit 53 changes the arranged wire information so that the logical expression of the LUT is changed in accordance with the exchange of the input ports of the connection destinations of the wires (S606) and the processing proceeds to S607. On the other hand, when it is determined that the width of a glitch that occurs from the LUT is greater than the predetermined threshold value (S604), the processing proceeds to S607.

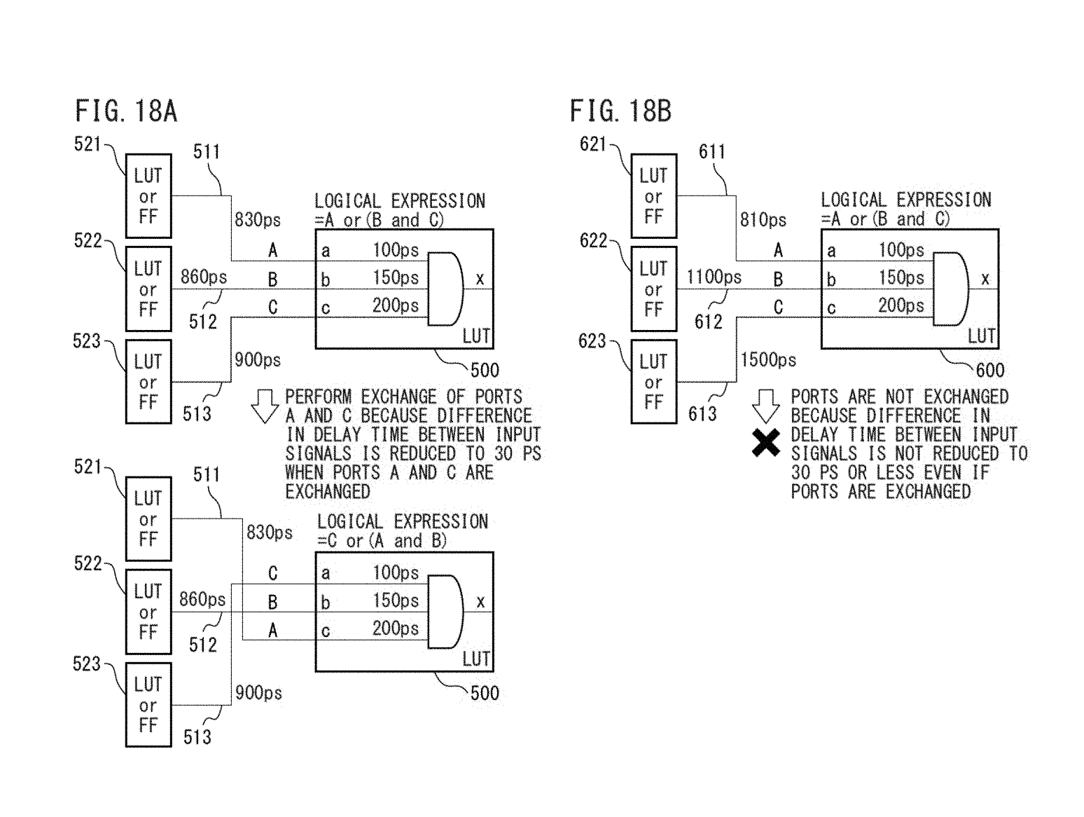

FIG. 18A is a diagram illustrating an example of an LUT and FIG. 18B is a diagram illustrating another example of an LUT.

First, the logical expression acquisition unit 31 acquires the logical expression of an LUT 500 from the arranged wire information stored in the storage unit 11 (S601). The logical expression of an LUT 500 is X=A or (B and C). Next, the cell delay amount acquisition unit 32 acquires the cell delay amount of the LUT 500 from the arranged wire information stored in the storage unit 11 (S602). A first cell delay amount from a first input port a to the output terminal of the LUT 500 is 100 ps, a second cell delay amount from a second input port b to the output terminal of the LUT 500 is 150 ps, and a third cell delay amount from a third input port c to the output terminal of the LUT 500 is 200 ps. Next, the wire delay amount acquisition unit 33 acquires the wire delay amount of each of the wires connected to the input ports of the LUT 500 from the arranged wire information stored in the storage unit 11 (S603). A first wire delay amount of a first wire 511 is 830 ps, a second wire delay amount of a second wire 512 is 860 ps, and a third wire delay amount of a third wire 513 is 900 ps.

Next, the second change determination unit 51 determines whether the width of a glitch that occurs from the LUT 500 becomes less than or equal to a predetermined threshold value when the first wire 511 to the third wire 513 are exchanged (S604). The predetermined threshold value is 30 ps.

The second change determination unit 51 determines whether the width of a glitch that occurs from the LUT 500 becomes less than or equal to the predetermined threshold value by exchanging the connection destinations of the first wire 511 that is connected to the first input port a and the third wire 513 that is connected to the third input port c (S604).

Next, the second wire switch unit 52 exchanges the connection destinations of the first wire 511 that is connected to the first input port a and the third wire 513 that is connected to the third input port c (S605). When the connection destinations of the first wire 511 that is connected to the first input port a and the third wire 513 that is connected to the third input port c are exchanged, the total delay amount of a first input signal A becomes the sum of the first wire delay amount 830 ps and the third cell delay amount 200 ps, i.e., 1,030 ps. The total delay amount of a second input signal B is the sum of the second wire delay amount 860 ps and the second cell delay amount 150 ps, i.e., 1,010 ps. The total delay amount of a third input signal C is the sum of the third wire delay amount 900 ps and the first cell delay amount 100 ps, i.e., 1,000 ps. The difference between the total delay amount of the second input signal B and the total delay amount of the third input signal C is 20 ps, which is less than or equal to the threshold value.

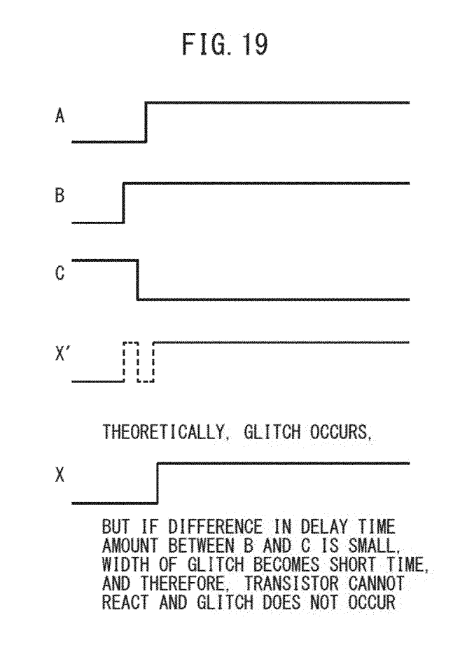

FIG. 19 is diagram showing an example of a timing chart of input/output signals of the LUT 500.

When the difference between the total delay amount of the second input signal B and the total delay amount of the third input signal C becomes less than or equal to the predetermined threshold value, the transistor forming the LUT 500 does not react, and therefore the LUT 500 does not cause a glitch to occur.

Next, the second logical expression change unit 53 changes the arranged wire information so that the logical expression of the LUT 500 is changed in accordance with the exchange of the input ports of the connection destinations of the wires (S606). In other words, the second logical expression change unit 53 changes the logical expression of the LUT 500 from the logical expression (X=A or (B and C)) into the logical expression (X=C or (A and B)).

By the processing unit 50 performing the processing at S505, the glitch width of a glitch becomes less than or equal to the threshold value. By the processing unit 50 performing the processing at S505, the glitch width of a glitch becomes less than or equal to the threshold value, and therefore a glitch does not occur and the occurrence of dynamic power consumption resulting from a glitch may be suppressed to the minimum.

The LUT 600 illustrated in FIG. 18B has a first input port a, a second input port b, a third input port c, and an output port x like the LUT 500 illustrated in FIG. 18A and is a combinational circuit configured to perform an arithmetic operation of the logical expression (X=A or (B and C)). A first input signal A is input from a first output cell 621 to the first input port a via a first wire 611 and to the second input port b, a second input signal B is input from a second output cell 622 via a second wire 612. A third input signal C is input from a third output cell 623 to the third input port c via a third wire 613.

First, the logical expression acquisition unit 31 acquires the logical expression of the LUT 600 from the arranged wire information stored in the storage unit (S601). The logical expression of the LUT 600 is X=A or (B and C). Next, the cell delay amount acquisition unit 32 acquires the cell delay amount of the LUT 600 from the arranged wire information stored in the storage unit 11 (S602). A first cell delay amount from the first input port a to the output terminal of the LUT 600 is 100 ps, a second cell delay amount from the second input port b to the output terminal of the LUT 600 is 150 ps, and a third cell delay amount from the third input port c to the output terminal of the LUT 600 is 200 ps. Next, the wire delay amount acquisition unit 33 acquires the wire delay amount of each of the wires connected to the input ports of the LUT 600 from the arranged wire information stored in the storage unit 11 (S603). A first wire delay amount of the first wire 611 is 810 ps, a second wire delay amount of the second wire 612 is 1,100 ps, and a third wire delay amount of the third wire 613 is 1,500 ps.

Next, the second change determination unit 51 determines whether the width of a glitch that occurs from the LUT 600 becomes less than or equal to a predetermined threshold value when the first wire 611 to the third wire 613 are exchanged (S604). The second change determination unit 51 determines that the width of a glitch that occurs from the LUT 600 becomes greater than the predetermined threshold value when the first wire 611 to the third wire 613 are exchanged (S604), and the processing proceeds to S607.

At S607, the logical expression acquisition unit 31 determines whether the logical expressions of all the LUTs included in the arranged wire information have been acquired (S607). Until the logical expression acquisition unit 31 determines that the logical expressions of all the LUTs included in the arranged wire information have been acquired, the processing at S601 to S607 is repeated. Each time the processing at S601 to S607 is performed, whether the width of a glitch that occurs from the LUT becomes less than or equal to the predetermined threshold value is determined (S604). When it is determined that the width of a glitch that occurs from the LUT becomes less than or equal to the predetermined threshold value (S604), the wires that are connected to the input ports are exchanged so that the width of a glitch that occurs from the LUT becomes less than or equal to the predetermined threshold value (S605). Next, the logical expression of the LUT is changed in accordance with the exchange of the input ports of the connection destinations of the wires. Then, when the logical expression acquisition unit 31 determines that the logical expressions of all the LUTs included in the arranged wire information have been acquired (S607), the processing at S505 is terminated.

### Working and Effect of Programmable Logic Device Designing Apparatus According to Embodiment

The PLD designing apparatus according to the embodiment exchanges the input ports of the connection destinations of the wires connected to at least two input ports of the LUT and the logical expressions so that the input order coincides with the input order corresponding to the logical expression of the LUT stored in the input port change table. The PLD designing apparatus according to the embodiment theoretically minimizes the number of glitches and reduces the dynamic power consumption resulting from a glitch by exchanging the input ports of the connection destinations of the wires connected to at least two input ports of the LUT and the logical expressions.

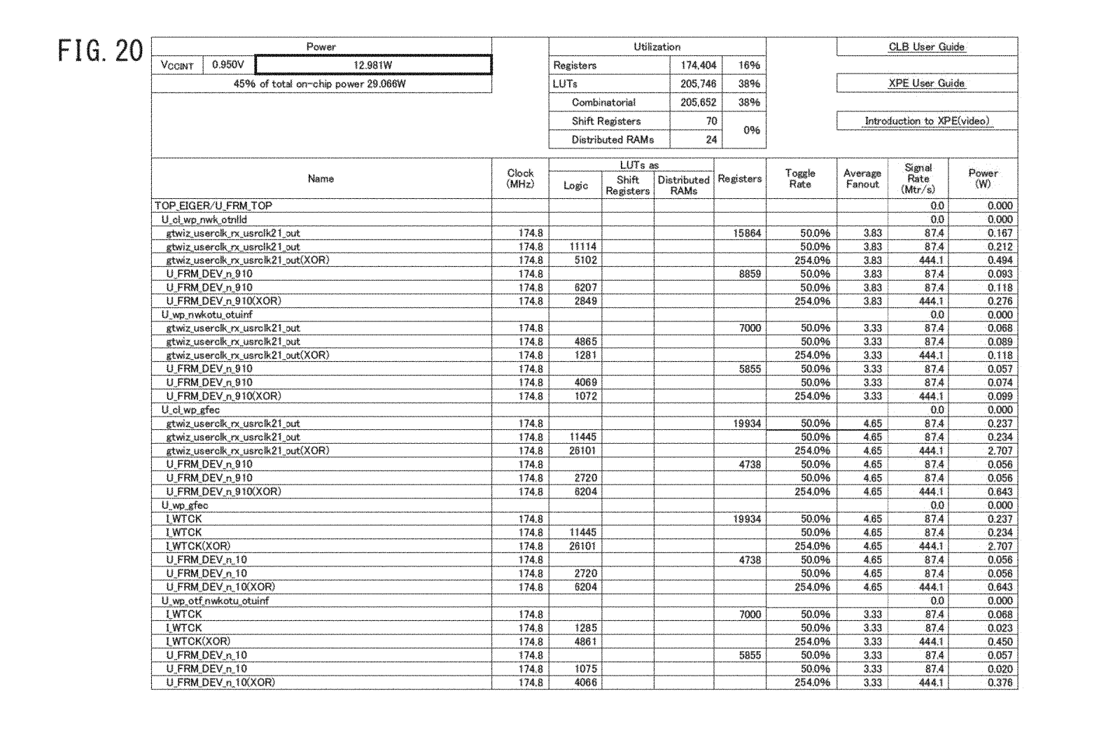

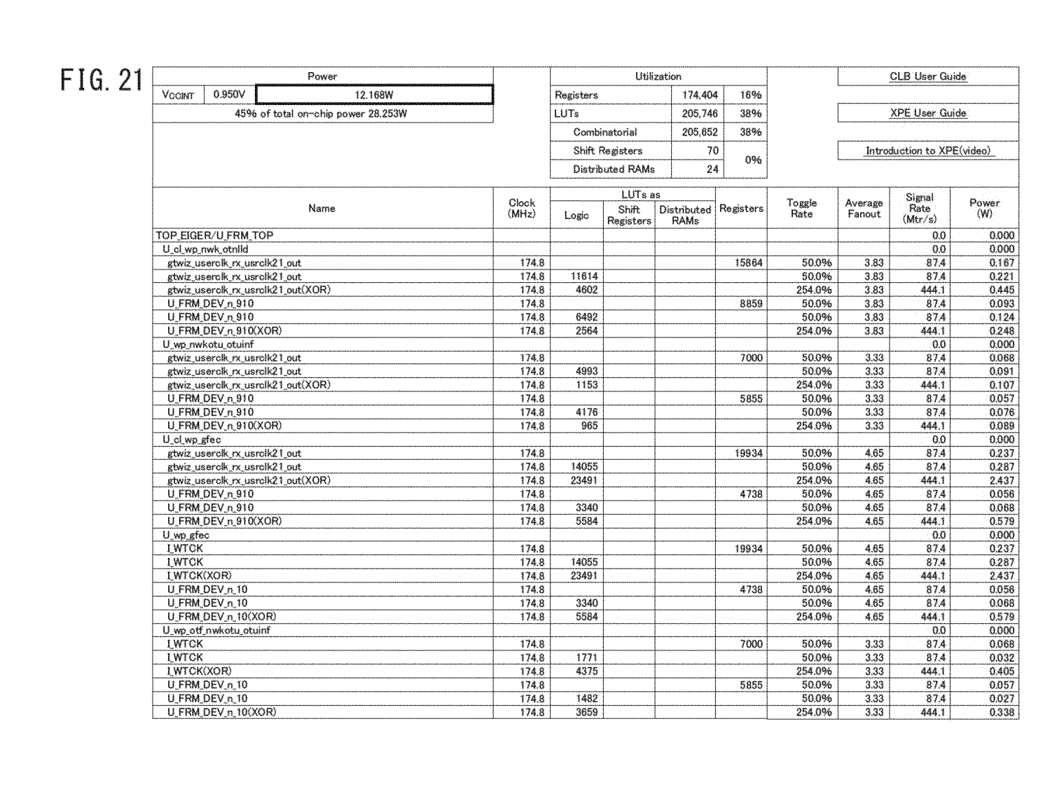

FIG. 20 is a diagram illustrating the state of configuration data for which the configuration data generation processing by the PLD designing apparatus 1 is not performed. FIG. 21 is a diagram illustrating the state of configuration data for which the configuration data generation processing by the PLD designing apparatus 1 has been performed. In FIG. 21, the PLD designing apparatus 1 has performed the processing at S103 for the LUTs of 10% of the LUTs that are mounted on the FPGA.

By performing the processing at S103 by the PLD designing apparatus 1, the dynamic power consumption of the FPGA has been reduced from 12.981 W to 12.168 W. By performing the processing at S103 by the PLD designing apparatus 1, the dynamic power consumption has been reduced by 6.3%.

Further, the PLD designing apparatus connects any of the wires connected to the input ports of the LUT to the unused input port so that the input order coincides with the input order corresponding to the logical expression of the LUT stored in the input port change table. The PLD designing apparatus according to the embodiment theoretically minimizes the number of glitches and further reduces the dynamic power consumption resulting from a glitch by connecting any of the wires connected to the input ports of the LUT to the unused input port.

Furthermore, the PLD designing apparatus exchanges the input ports of the connection destinations of the wires connected to the input ports of the LUT and the logical expressions so that the width of a glitch that is caused to occur by the LUT becomes less than or equal to the predetermined threshold value. The PLD designing apparatus according to the embodiment theoretically minimizes the number of glitches and further reduces the dynamic power consumption resulting from a glitch by exchanging the input ports of the connection destinations of the wires connected to the input ports of the LUT and the logical expressions.

### Modification Example of Programmable Logic Device Designing Apparatus According to Embodiment

The PLD designing apparatuses 1 to 3 have the first change determination unit 34 configured to determine whether the input order of the input signals that are input to the LUT coincides with the input order stored in the input port change table when the wires are exchanged. However, the PLD designing apparatuses according to the embodiments do not have to have the first change determination unit 34. When the PLD designing apparatuses according to the embodiments do not have the first change determination unit 34, the first wire switch unit 35 exchanges the wires of all the LUTs included in the arranged wire information so that the input order coincides with the input order stored in the input port change table.

Further, the PLD designing apparatus according to the third embodiment has the input port determination unit 41, the unused input port determination unit 42, the unused input port connection unit 43, and the unused logical expression change unit 44. However, i the PLD designing apparatus according to the embodiment may have the second change determination unit 51, the second wire switch unit 52, and the second logical expression change unit 53 without having the input port determination unit 41, the unused input port determination unit 42, the unused input port connection unit 43, and the unused logical expression change unit 44. When not having the input port determination unit 41, the unused input port determination unit 42, the unused input port connection unit 43, and the unused logical expression change unit 44, the PLD designing apparatus according to the embodiment omits the processing at S504 and performs the processing at S501 to S503 and S505 to S507.

All examples and conditional language provided herein are intended for pedagogical purposes of aiding the reader in understanding the invention and the concepts contributed by the inventor to furthering the art, and are to be construed as limitations to such specifically recited examples and conditions, nor does the organization of such examples in the specification relate to a illustrating of the superiority and inferiority of the invention. Although one or more embodiments of the present invention have been described in detail, it should be understood that the various changes, substitutions, and alterations could be made hereto without departing from the spirit and scope of the invention.

What is claimed is:

1. A non-transitory computer-readable recording medium having stored there in a designing program of a programmable logic device that causes a computer to execute a process comprising:
acquiring a logical expression of a combinational circuit from arranged wire information on a programmable logic device;
acquiring a wire delay amount connected to an input port of the combinational circuit from the arranged wire information;
exchanging input ports of connection destinations of wires connected to at least two input ports of the combinational circuit based on a cell delay amount of the combinational circuit and the wire delay amount so that an input order of input signals of the combinational circuit coincides with an input order corresponding to the logical expression of the combinational circuit stored in an input port change table showing a relationship between the logical expression of the combinational circuit and an input order of input signals that are input to the combinational circuit, which minimizes the number of glitches in the combinational circuit; and
changing the logical expression of the combinational circuit in accordance with the exchange of the input ports of the connection destinations of the wires.

2. The non-transitory computer-readable having stored there in the designing program recording medium according to claim 1, further comprising:
determining whether the input order of input signals that are input to the combinational circuit coincides with the input order stored in the input port change table when the wires are exchanged from the wire delay amount and the cell delay amount of the combinational circuit, wherein
exchanging the input ports of the connection destinations of the wires is performed when it is determined that the input order of input signals that are input to the combinational circuit coincides with the input order stored in the input port change table.

3. The non-transitory computer-readable recording medium having stored there in the designing program according to claim 2, further comprising:
determining whether an unused input port to which no input signal is input exists in the combinational circuit when it is determined that the input order of input signals that are input to the combinational circuit does not coincide with the input order stored in the input port change table;
determining whether the input order of input signals that are input to the combinational circuit coincides with the input order stored in the input port change table when any of the wires is connected to the unused input port when it is determined that the unused input port exists;
connecting any of the wires to the unused input port so that the input order of input signals that are input to the combinational circuit coincides with the input order corresponding to the logical expression of the combinational circuit stored in the input port change table when it is determined that the input order of input signals that are input to the combinational circuit coincides with the input order stored in the input port change table; and
changing the logical expression of the combinational circuit in accordance with the connection of the wire to the unused input port.

4. The non-transitory computer-readable recording medium having stored there in the designing program according to claim 2, further comprising:
determining whether the width of a glitch that occurs from the combinational circuit becomes less than or equal to a predetermined threshold value when the wires are exchanged from the wire delay amount and the cell delay amount of the combinational circuit when it is determined that the input order of input signals that are input to the combinational circuit does not coincide with the input order stored in the input port change table;
exchanging the input ports of the connection destinations of the wires connected to the input ports so that the width of a glitch that occurs in the combinational circuit becomes less than or equal to the predetermined threshold value when it is determined that the width of a glitch that occurs in the combinational circuit becomes less than or equal to the predetermined threshold value; and
changing the logical expression of the combinational circuit in accordance with the exchange of the input ports of the connection destinations of the wires.

5. A designing method of a programmable logic device, the method comprising:
acquiring a logical expression of a combinational circuit from arranged wire information on a programmable logic device;
acquiring a wire delay amount connected to an input port of the combinational circuit from the arranged wire information;
exchanging input ports of connection destinations of wires connected to at least two input ports of the combinational circuit based on a cell delay amount of the combinational circuit and the wire delay amount so that an input order of input signals of the combinational circuit coincides with an input order corresponding to the logical expression of the combinational circuit stored in an input port change table showing a relationship between the logical expression of the combinational circuit and an input order of input signals that are input to the combinational circuit, which minimizes the number of glitches that occur in the combinational circuit; and
changing the logical expression of the combinational circuit in accordance with the exchange of the input ports of the connection destinations of the wires.

6. A programmable logic device designing apparatus comprising:
a storage unit configured to store arranged wire information on a programmable logic device and an input port change table showing a relationship between a logical expression of a combinational circuit and an input order of input signals that are input to the combinational circuit, which minimizes the number of glitches that occur in the combinational circuit;
a logical expression acquisition unit configured to acquire the logical expression of the combinational circuit from the arranged wire information;
a wire delay amount acquisition unit configured to acquire a wire delay amount connected to an input port of the combinational circuit from the arranged wire information;
a first wire switch unit configured to exchange input ports of connection destinations of wires connected to at least two input ports of the combinational circuit based on a cell delay amount of the combinational circuit and the wire delay amount so that the input order of input signals of the combinational circuit coincides with the input order corresponding to the logical expression of the combinational circuit stored in the input port change table; and
a first logic change unit configured to change the logical expression of the combinational circuit in accordance with the exchange of the input ports of the connection destinations of the wires.
